(19) United States
(12) Patent Application Publication
(10) Pub. No.: US 2019/0089044 A1
(43) Pub. Date: Mar. 21, 2019

(54) MULTILAYER INTERCONNECTION SUBSTRATE FOR HIGH FREQUENCY AND MANUFACTURING METHOD THEREOF

(71) Applicant: SNAPTRACK, INC., San Diego, CA (US)

(72) Inventors: Hisashi KOBUKE, (US); Naoki SOTOMA, San Diego, CA (US); Yousuke FUTAMATA, San Diego, CA (US); Emi NINOMIYA, San Diego, CA (US); Atsushi ISHIMOTO, San Diego, CA (US)

(21) Appl. No.: 16/086,333

(22) PCT Filed: Mar. 31, 2017
(86) PCT No.: PCT/US2017/025521

§ 371 Date: Sep. 19, 2018

(30) Foreign Application Priority Data
Mar. 31, 2016 (JP) 2016-072802

(51) Int. Cl. H01Q 1/38; H01L 23/498; H01L 23/66; H01L 23/15; H01L 21/48; H05K 1/11; H05K 1/02; H05K 3/46; H05K 1/03; H01Q 9/04; H01Q 1/22

(52) U.S. Cl. CPC H01Q 1/38; H05K 3/0029; H01L 23/49827; H01L 23/66; H01L 23/15; H01L 21/4857; H01L 21/4807; H05K 1/115; H05K 1/024; H05K 3/4667; H05K 1/0306; H01Q 9/0414; H01Q 1/2283; H01L 2223/6677; H05K 2201/0209; H05K 2201/10098; H05K 2203/1131; H05K 2201/10015; H01L 23/49822

(57) ABSTRACT

[Problem] To realize high reliability and high functionalization while suppressing characteristics variation in a multilayer interconnection substrate used in a microwave or millimeter-wave band integrated with an antenna. [Resolution Means] A multilayer substrate for high frequency with an antenna element formed on a surface. The multilayer substrate for high frequency has an intermediate substrate. The intermediate substrate consists of a low-temperature co-fired glass-ceramic substrate and has intermediate insulating layers consisting of a glass-ceramic and an internal conductor formed between these intermediate insulating layers. A surface insulating layer consisting of an organic material having a dielectric constant lower than a glass-ceramic material is stacked on a surface of the intermediate substrate. An outer-side via conductor penetrating this surface insulating layer is configured by a sintered metal that forms a metallic bond with a wiring conductor in the substrate. The outer-side via conductor is formed at the same time as sintering the glass-ceramic multilayer substrate.

### CROSS-REFERENCE TO RELATED APPLICATION & PRIORITY CLAIM

This application claims benefit of and priority to Japanese Patent Application Serial No. JP 2016-72802, filed Mar. 31, 2016, which is herein incorporated by reference in its entirety.

### FIELD

The present invention relates to a multilayer interconnection substrate for high frequency and a manufacturing method thereof and relates more particularly to a multilayer interconnection substrate for high frequency suitable for a system using a high frequency such as a microwave or a millimeter wave.

### BACKGROUND

In recent years, development of communication systems using a microwave and a millimeter wave is actively underway and development of a device for high frequency used in these instruments is also underway. Microwaves and millimeter waves are known for having characteristics such as a broad band, a high resolution, and a short wavelength. Because these characteristics enable large-capacity communication, high-speed data transmission, and size and weight reduction of an instrument and simultaneously have merits such as interference with another communication system being small, in recent years, use in a system such as a high-speed wireless LAN or an in-vehicle radar is being actively developed.

Such a system is normally configured from an antenna, a high-frequency device such as a high-frequency oscillator or amplifier, and a transmission line connecting the antenna and the high-frequency device or the high-frequency devices to each other.

As a method of configuring a system of a high-frequency band, research for attempting to implement the system in a form of a system on package (SOP) for size reduction and cost reduction of a product is actively underway. As a technology of such a system on package, low-temperature co-fired ceramic (LTCC) technology is being considered as one of the most suited technologies.

Low-temperature co-fired ceramic technology is fundamentally a technology using a multilayer substrate and has an advantage of having passive elements such as a capacitor, an inductor, and a filter built in inside the substrate to be able to realize size reduction and a performance increase of a module.

Furthermore, in these systems, losses in antenna performance and the transmission line are functionally important elements.

From such a viewpoint of performance improvement, a low-temperature co-fired ceramic uses a glass-ceramic material with little dielectric loss. A glass-ceramic material is an effective means due to advantages of a relative dielectric constant being able to be comparatively small and a metal material with a low melting point and a low resistance such as Cu, Ag, or Ag—Pd being able to be used for wiring of an inner layer as well as from a viewpoint of loss reduction as a substrate material and the loss in the transmission line, which is created by the wiring of the inner layer, being able to be reduced.

Furthermore, to reduce transmission loss between the antenna and the high-frequency device, a waveguide with little transmission loss is conventionally used as the transmission line; using a multilayer substrate using a low-temperature-sintered ceramic to be able to readily mold a configuration thereof in hopes of performance improvement is also a reason for the considerations in recent years.

As described above, in a configuration of a system using a system on package, antenna performance is thought to be a core component swaying a performance of an implemented system.

Generally, in a situation of producing a patch antenna operating in a millimeter-wave frequency band, particularly a super-high frequency band of 60 GHz or more, leakage of a signal arises in a form of a surface wave flowing along a surface of a dielectric substrate in the patch antenna. Such leakage of the signal increases the more a thickness of the substrate increases and the higher a dielectric constant of the substrate. Such leakage of the signal causes a radiant efficiency of the patch antenna to drop and reduces an antenna gain.

Currently, productized modules of a millimeter-wave band are created in a form of a system on package by using low-temperature co-fired ceramic technology to reduce cost.

However, because a dielectric constant of a material used for a ceramic substrate such as a low-temperature co-fired ceramic is higher than that of an organic substrate, when an antenna function is mounted, a radiant efficiency and a gain of a high-dielectric-constant antenna are reduced. Because of this, to improve an efficiency of the antenna, a number of antennas is increased; however, increasing the number of antennas increases an area, which results in increasing a module area. Because of this, cost reduction and advantages of low-temperature co-fired ceramic technology are insufficiently utilized.

Therefore, in recent years, using a low dielectric constant in an antenna function is being considered.

As an example thereof, a structure forming only a surface-layer portion of a glass-ceramic multilayer interconnection substrate by a ceramic material with a lower dielectric constant than an inner-layer portion and a structure affixing a resin substrate molded in advance with an antenna portion to a surface-layer portion of a glass-ceramic multilayer interconnection substrate are being proposed and considered.

Patent literature 1 below proposes combining two LTCC tape systems having different dielectric constants (one having a low k and the other having a high k). Patent literature 1 proposes a method whereby an inexpensive substrate material having properties of both a low-k material and a high-k material can be manufactured readily for a single monolith multilayer circuit board for transceiver use or another circuit use such as a receiver or a transmitter.

Furthermore, a structure using a resin-material substrate that is a low-dielectric-constant material to create a substrate molded with an antenna and afterward affixing this to a glass-ceramic multilayer interconnection substrate is also being considered.

However, with patent literature 1, in a substrate use such as an antenna array where a large area is necessary, mounting failure may arise, heat stress due to temperature change may increase, and a defect due to a difference in material properties such as warping or cracking of the substrate may arise.

While a structure of affixing an organic-material substrate molded with an antenna to a glass-ceramic multilayer substrate and integrating these as a module is also proposed, not only is positioning when affixing difficult, readily becoming a cause of characteristics variation, but also high adhesion is difficult to ensure, and there is a problem in improving reliability.

Furthermore, in a situation of affixing the organic-material substrate, direct intermetallic bonding with a conductor in a glass-ceramic is difficult, forcing intermetallic bonding by soldering or the like; however, use of solder, which has a large resistivity, invites reduction of electrical characteristics in a high-frequency band and is not preferable.

Additionally, as used in a build-up multilayer structure that is one general resin multilayer substrate, it is also conceivable to machine a via hole by a laser or the like after coating a resin layer on a substrate and forming a metal therein by plating or the like to form a via conductor for connection. It is also conceivable to use this technique to perform wiring while forming a resin layer of a low dielectric constant on a glass-ceramic multilayer interconnection substrate. However, in a situation of machining by the laser or the like, because the via is formed based on an alignment mark formed on the glass-ceramic multilayer interconnection substrate, a shift in positions may arise at times of position detection of this alignment and laser machining.

Furthermore, in a situation of machining by the laser, a dimensional difference between an upper portion and a lower portion of the via conductor increases readily, and such a tapered conductor is undesirable in terms of high-frequency characteristics. Moreover, in a situation where a formed resin layer is thick, filling of the plating is difficult and a void arises readily in a plating conductor; this is once again undesirable in high-frequency use, particularly in forming and connecting an element such as an antenna.

Furthermore, in many situations, these techniques have wiring as an object such that a quality of the via conductor in a high-frequency band is not taken into consideration.

### CITATION LIST

Patent Literature 1 JP 2013-518029A

### SUMMARY

### Technical Problem

From such viewpoints, an object of the present invention is to provide a multilayer circuit board for high frequency having little variation in characteristics and an antenna function that does not cause electrical loss and a manufacturing method thereof.

### Solution to Problem

To achieve the object above, a multilayer interconnection substrate for high frequency according to the present invention is a multilayer interconnection substrate for high frequency, comprising:

i) an intermediate substrate where an internal conductor layer of a predetermined pattern is formed between a plurality of intermediate insulating layers consisting of a glass-ceramic or on a surface of an intermediate insulating layer;
ii) an intermediate via conductor that penetrates the intermediate insulating layer and connects the internal conductor layers present in different interlayer positions to each other;
iii) a surface insulating layer consisting of an organic material integrally formed on at least one surface of the intermediate substrate; and
iv) an outer-side via conductor that penetrates the surface insulating layer and connects the internal electrode layer or the intermediate via electrode and an antenna element disposed on an outer side of the surface insulating layer; wherein the outer-side via conductor is configured by a sintered metal integrally sintered with the internal conductor layer or the intermediate via conductor and a relative dielectric constant of the surface insulating layer is lower than a relative dielectric constant of the intermediate insulating layer.

By adopting the structure above, it is possible to perform wiring by forming a low-dielectric-constant layer on a surface of the intermediate substrate consisting of the glass-ceramic multilayer interconnection substrate with precision and without causing electrical loss.

Furthermore, by adopting the structure above, the internal conductor layer of the predetermined pattern in the glass-ceramic multilayer substrate and the outer-side via conductor penetrating the surface insulating layer consisting of the organic material are configured by an integrally-sintered sintered metal, realizing an intermetallic bond there between. This enables electrical-signal-loss suppression in a high-frequency band such as a millimeter wave or a microwave and is an element of suppressing characteristics reduction in the high-frequency band.

Furthermore, because intermetallic bonding takes place by the internal conductor layer or the intermediate via electrode and the outer-side via conductor being configured by the integrally-sintered sintered metal, an outer-side via conductor with excellent positional precision and little tapering can be provided. Because of this, it becomes possible to maximize antenna characteristics and a multilayer circuit board for high frequency with little quality variation and formed with an antenna with excellent characteristics can be provided.

Furthermore, because forming the antenna element on the surface insulating layer that is a low-dielectric-constant layer reduces a difference in dielectric constants with air, an electromagnetic wave is more readily propagated over the dielectric substrate surface and more readily radiated into a space in a direction perpendicular to an antenna face; as a result, gain improvement and radiant-efficiency improvement of the antenna comes to be expected.

Preferably, an inclination ratio between a narrowest portion and a broadest portion of the outer-side via conductor is 10% or less.

Here, the inclination ratio above can be defined as below.

Inclination ratio (%)=[(longest distance between a center of gravity in a cross section of the via conductors 4a, 4b in a direction perpendicular to a direction in which an electrical signal is transmitted and an outer peripheral portion)−(shortest distance between the center of gravity in the cross section of the via conductors 4a, 4b in the direction perpendicular to the direction in which the electrical signal is transmitted and the outer peripheral portion)]/(longest distance between the center of gravity in the cross section of the via conductors 4a, 4b in the direction perpendicular to the direction in which the electrical signal is transmitted and the outer peripheral portion)

In this manner, by using a conductor with little change in a cross-sectional shape in the direction perpendicular to the direction in which the electrical signal is transmitted in the conductor using the sintered metal, compatibility is enabled with making an organic-material layer thick without impairing a quality of the via conductor. This also enables forming a via conductor with little electrical loss without taking into consideration design factors such as a thickness of the organic-material layer.

Preferably a surface roughness Ra (μm) of the intermediate substrate at an interface between the intermediate substrate and the surface insulating layer is in a range of 0.1≤Ra≤1.0.

By controlling a surface state of the intermediate substrate consisting of the glass-ceramic material as above, high bonding and adhesion can be ensured and a module with no quality problems can be realized.

Generally, with an organic material and a glass-ceramic material, not only is there a difference in coefficients of linear expansion but also adhesion improvement by chemical bonding is difficult. Because of this, adhesion by a physical anchor by roughening a surface on a glass-ceramic side on which adhesion is to take place is desirable; however, if the roughness is too small, adhesion cannot be sufficiently ensured, which becomes a cause of peeling. Moreover, in a situation where this is too rough, when affixing the organic material, a void remains more readily at the interface, and reduction in reliability due to an influence of moisture or the like after productization becomes a concern. Therefore, it is thought that providing an appropriate surface roughness is a cause of high adhesion being able to be realized.

An average particle size D50 (μm) of the ceramic filler in an outermost layer of the intermediate substrate at the interface between the intermediate substrate and the surface insulating layer may be 0.2≤D50≤5.0. By configuring in this manner, more stable adhesion between the intermediate substrate and the surface insulating layer becomes possible.

The glass-ceramic material is configured by a glass and a ceramic filler; however, a surface state of the glass-ceramic at the time of firing is readily affected by a shape of the filler, and a form thereof depends on the filler.

With this, chemical etching or physical etching such as blasting can be used as a means of roughening; however, because a difference is seen in how the glass and the ceramic filler are etched, the filler shape is an important element in forming the surface state.

It is thought that by controlling the shape to be in a range such as above the surface of the intermediate substrate enters a surface state where high adhesion can be expected. With this, it is thought that a microscopic roughness being formed due to the filler shape, thereby enabling a roughness suited to adhesion to be realized, is one cause. Moreover, as another element, this is thought to be because by a ceramic serving as this filler being present in a vicinity of the surface, it becomes possible to adhere the organic material to the ceramic, which is more chemically stable than glass, enabling more stable adhesion to be realized.

Preferably, the relative dielectric constant of the surface insulating layer is 2 or more and 4 or less. By making the dielectric constant small, a system including an antenna with more favorable performance can be realized. Generally, material loss of the organic material is greater than that of the ceramic, but by making the dielectric constant sufficiently small, a radiant efficiency of the antenna can be increased.

Preferably, the intermediate substrate is a low-temperature-sintered glass-ceramic substrate. Providing a module integrally formed with an antenna on the surface insulating layer of the low dielectric constant formed on the surface of this intermediate substrate maximizes advantages of size reduction and cost reduction of the module by having passive components such as a capacitor, an inductor, and a filter built in inside the substrate.

A method of manufacturing a multilayer interconnection substrate for high frequency of the present invention comprises:

i) a step of preparing a green sheet for shrinkage suppression where a conductive paste that comes to be the outer-side via conductor is embedded in a predetermined pattern so as to penetrate a surface and a rear face;
ii) a step of respectively stacking the green sheet for shrinkage suppression on both faces of a green-sheet stacked body that comes to be the intermediate substrate;
iii) a step of firing the green-sheet stacked body together with the green sheet for shrinkage suppression;
iv) a step of removing the fired green sheet for shrinkage suppression leaving the outer-side via conductor consisting of the fired conductive paste on the surface of the fired green-sheet stacked body to form an intermediate substrate with an outer-side via conductor; and
v) a step of forming a surface insulating layer consisting of an organic material on a surface of the intermediate substrate with the outer-side via conductor.

According to the method of manufacturing a multilayer interconnection substrate for high frequency of the present invention, the multilayer interconnection substrate for high frequency of the present invention described above can be manufactured efficiently while suppressing warping of the intermediate substrate. That is, the multilayer interconnection substrate can be formed by no-shrinkage firing.

By using no-shrinkage firing technology, intermetallic bonding between a wiring conductor in the ceramic multilayer substrate and the via conductor can be realized with precision and more readily. With this, taking advantage of the via conductor for connection being able to be formed in the shrinkage-suppression sheet that is not sintered at the time of firing used at the time of no-shrinkage firing is effective in facilitating formation of a via conductor with a large height and little tapering.

### BRIEF DESCRIPTION OF DRAWINGS

FIG. 1A is a schematic cross-sectional view of a multilayer interconnection substrate for high frequency according to one embodiment of the present invention.

FIG. 1B is a schematic cross-sectional view of a multilayer interconnection substrate for high frequency according to another embodiment of the present invention.

FIG. 2 is a schematic cross-sectional view of an intermediate substrate illustrated in FIG. 1A.

FIG. 3 is a schematic cross-sectional view illustrating a manufacturing process of the multilayer interconnection substrate for high frequency illustrated in FIG. 1A.

FIG. 4 is a schematic cross-sectional view illustrating a step in continuation from FIG. 3.

FIG. 5 is a schematic cross-sectional view illustrating a step in continuation from FIG. 4.

FIG. 6 is a schematic cross-sectional view illustrating a step in continuation from FIG. 5.

FIG. 7 is a schematic cross-sectional view illustrating a step in continuation from FIG. 6.

FIG. 8 is a schematic cross-sectional view illustrating a step in continuation from FIG. 7.

FIG. 9A is a partial schematic cross-sectional view illustrating a positional relationship between a tapered outer-side via conductor and an intermediate via conductor.

FIG. 9B is a schematic view illustrating an inclination ratio of the tapered outer-side via conductor.

FIG. 10A is a partial schematic cross-sectional view illustrating a positional shift between the outer-side via conductor and the intermediate conductor.

FIG. 10B is a schematic plan view illustrating the positional shift.

### DESCRIPTION OF EMBODIMENTS

A multilayer interconnection substrate for high frequency and a manufacturing method according to one embodiment of the present invention is described in detail below with reference to the drawings.

### First Embodiment

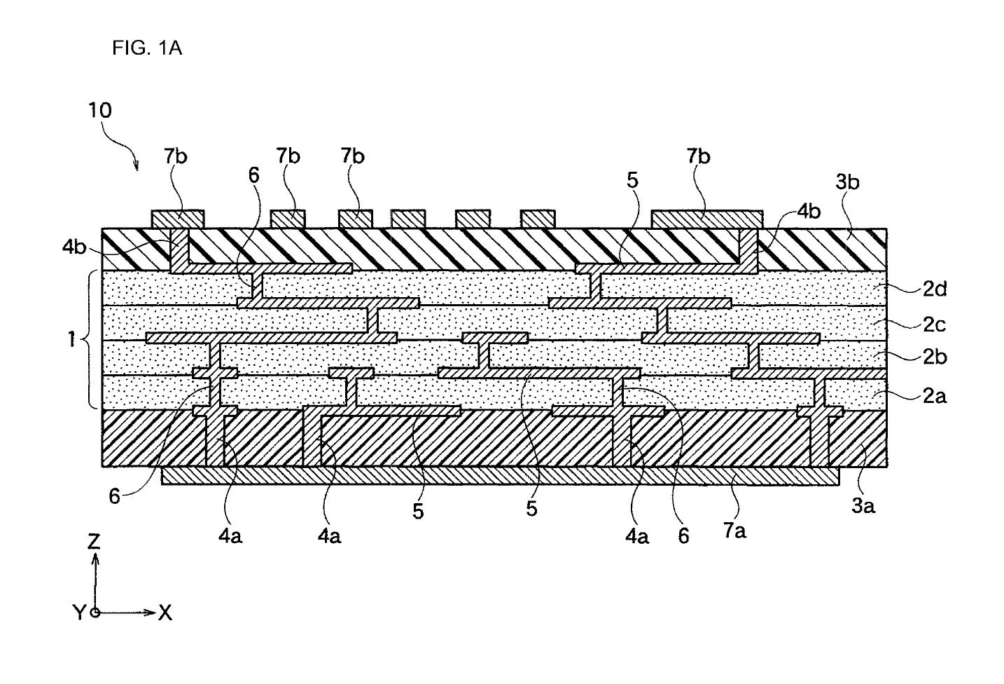

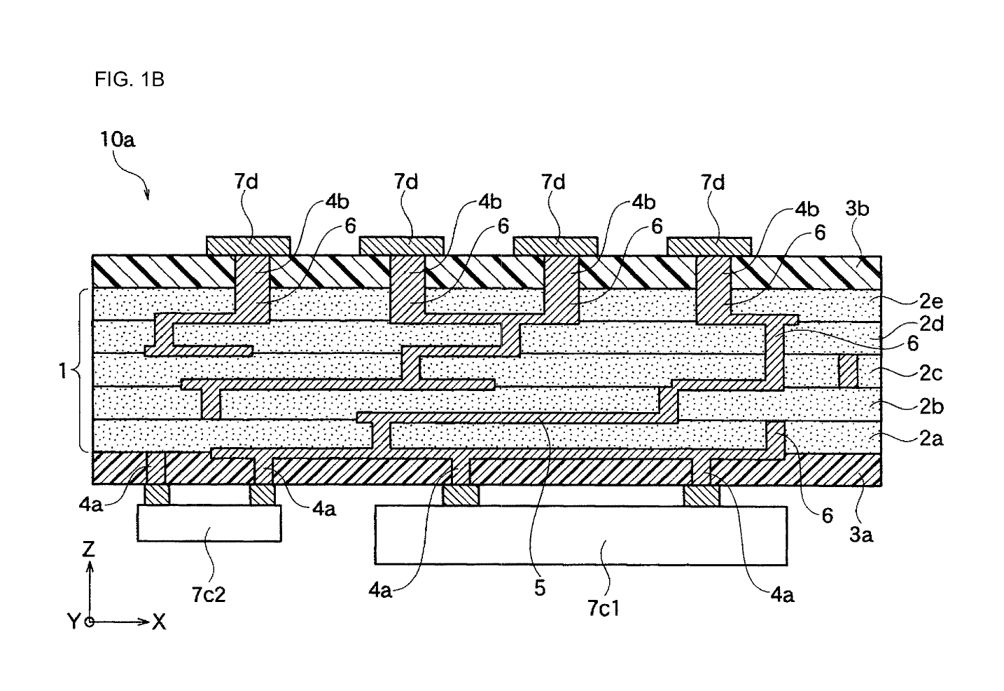

The multilayer interconnection substrate for high frequency of the present embodiment is a substrate suitable for use as a component of a module for high frequency. A multilayer interconnection substrate for high frequency 10 illustrated in FIG. 1 has an intermediate substrate 1 and surface insulating layers 3a, 3b consisting of an organic material stacked contacting both faces of the intermediate substrate 1.

The intermediate insulating substrate 1 has a plurality of stacked and integrated intermediate insulating layers 2a to 2d consisting of a glass-ceramic and is a low-temperature-fired (LTCC) substrate configured by a glass-ceramic that can be fired at a low temperature of, for example, 1,000° C. or less. An internal conductor layer 5 is formed in a predetermined electrode pattern between each intermediate insulating layer 2a to 2d or on an outer-side surface of the intermediate insulating layers 2a to 2d. To electrically connect each internal conductor layer 5, a through hole penetrating the surface and a rear face is formed in the intermediate insulating layers 2a to 2d and an intermediate via conductor 6 is embedded in this through hole, connecting the internal conductor layers 5 to each other. Note that the intermediate via conductor 6 also has an action of dissipating heat accumulated inside the intermediate substrate 1 to the outside.

Furthermore, while not illustrated, elements such as an inductor, a capacitor, and a filter may be built in inside the intermediate substrate 1. As a ceramic material configuring the intermediate substrate 1, any general glass-ceramic material used in this type of ceramic multilayer substrate can be used.

The glass-ceramic configuring the intermediate insulating layers 2a to 2d of the intermediate substrate 1 is generally configured by a glass and a ceramic filler. As the glass, a glass powder consisting of at least one type from among (1) an amorphous glass material and (2) a crystallized glass material can be mentioned. Particularly, (2) the crystallized glass material is a material where a large number of fine crystals precipitates into a glass component at a time of heating and firing and, by being imparted with high crystallinity, can reduce dielectric loss, making it suitable for use in a microwave or millimeter-wave band.

As (2) the crystallized glass material, there is, for example, (i) a glass containing SiO₂, B₂O₃, Al₂O₃, and an alkaline-earth-metal oxide and (ii) a diopside crystal glass containing SiO₂, CaO, MgO, Al₂O₃, and SrO₂, but this material is not limited thereto, and any material can be used as appropriate as long as it can be sintered at 1,000° C. or less.

The ceramic filler is configured by a ceramic filler formed by a material including at least one type selected from a group consisting of alumina, magnesia, spinel, silica, mullite, forsterite, steatite, cordierite, strontium feldspar, quartz, zinc silicate, zirconia, and titania.

A ratio of the ceramic filler is preferably inclusion at 20% by mass to 40% by mass of a glass-ceramic sintered body. A component other than the components above may be included in a range that does not impair characteristics such as dielectric loss.

The intermediate via conductor 6 and the internal conductor layer 5 of the intermediate substrate 1 consist of a sintered metal. A conductive material configuring these is not particularly limited, but, for example, a metal such as Ag, Pd, Au, or Cu can be used. Note that outer-side via conductors 4a, 4b described below are configured by the same conductive material as the intermediate via conductor 6 and/or the internal conductor layer 5 and are preferably integrated with the intermediate via conductor 6 and/or the internal conductor layer 5, which they contact.

The outer-side insulating layers 3a, 3b consisting of the organic material are configured by a resin material. Any resin material can be used as long as it is a resin material that can be molded into a sheet shape, a film shape, or the like. For example, as the resin material, both a thermoplastic resin and a thermosetting resin can be used; specifically, there is an epoxy resin, a phenol resin, a bismaleimide-triazine resin, a cyanate-ester resin, a polyamide, a polyolefin resin, a polyester, a polyphenylene-oxide resin, a liquid-crystal polymer, a silicone resin, a fluororesin, and the like, and these can be used independently or in a plurality, combined. Moreover, the resin material may contain an inorganic filler such as a ceramic.

By using a material such as above, a low dielectric constant of the surface insulating layers 3a, 3b becomes possible; however, from a viewpoint of characteristics improvement of an antenna portion, a material whereby a relative dielectric constant becomes 4 or less is desirable.

Furthermore, as described above, from a viewpoint of adjusting the dielectric constant and mechanical properties, the inorganic filler such as the ceramic may be contained; however, from the viewpoint of characteristics improvement of the antenna portion, the relative dielectric constant is desirably 4 or less.

The outer-side via conductors 4a, 4b consisting of the sintered metal conductor consisting of the sintered metal are formed penetrating the outer-side insulating layers 3a, 3b consisting of the organic material. Any metal used in this type of substrate can be used as a material that can be used as the sintered metal conductor as long as it is a metal in a sintered state; for example, similarly to the internal conductor layer 5, a metal such as Ag, Pd, Au, or Cu; an alloy thereof; or the like can be used, Ag being preferable among these.

Furthermore, from viewpoints of ensuring low resistivity in the sintered metal conductor and reducing adhesion of a residue of a shrinkage suppression sheet, the sintered metal conductor may include the metal oxide component above and a glass component but desirably has a metal content of at least 95% or more from a viewpoint of electrical characteristics.

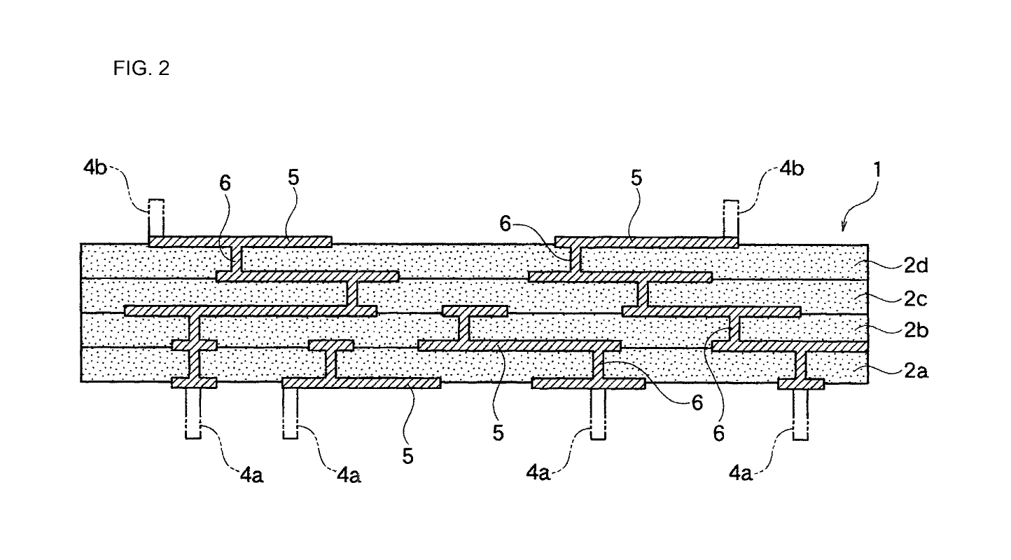

As illustrated in FIG. 2, the outer-side via conductors 4a, 4b consisting of the sintered metal conductor can be formed in a columnar shape and be imparted with a function of, for example, a mark for positioning a pattern of the outer-side insulating layers 3a, 3b consisting of the organic material. As the positioning, for example, positioning between an antenna pattern formed on a surface of the outer-side insulating layers 3a, 3b and the outer-side via conductors 4a, 4b; positioning between the internal conductor layer of the intermediate substrate 1 and a surface-layer conductor (not illustrated) formed on the surface of the outer-side insulating layers 3a, 3b; and the like can be illustrated. In this manner, the outer-side via conductors 4a, 4b consisting of the sintered metal conductor can be imparted with not only a function as an interlayer connection via but also with an independent function as a mark for positioning or the like.

Providing the outer-side insulating layers 3a, 3b consisting of the organic material on a surface of the intermediate substrate 1 configured by the glass-ceramic also enables reduction of warping and unevenness of the surface of the intermediate substrate 1 consisting of the glass-ceramic, which can significantly improve surface smoothness compared to a conventional ceramic multilayer substrate.

Furthermore, as a result of the surface smoothness improving in this manner, in a situation of forming an antenna on a surface of the multilayer interconnection substrate 10, a resolution of photolithography can be increased; therefore, antenna molding with high dimensional precision becomes possible and reduction can also be expected in antenna-characteristics variation.

One example of a manufacturing method of the multilayer interconnection substrate for high frequency 10 illustrated in FIG. 1A is described below. First, an overview is described. In the present embodiment, the intermediate substrate 1 consisting of the ceramic multilayer substrate is created by using a so-called no-shrinkage firing method and simultaneously, the outer-side via conductors that penetrate the surface insulating layers 3a, 3b consisting of the organic material are formed. Note that the so-called no-shrinkage firing method is a method for suppressing shrinkage of a green sheet for a glass-ceramic substrate in an in-plane direction and allowing shrinkage only in a thickness direction.

By forming the outer-side via conductors 4a, 4b for connection at the same time as firing the intermediate substrate 1 consisting of the glass-ceramic multilayer substrate, improvement in positional precision between a conductor pattern of the internal conductor layer 5 in the intermediate substrate 1 and the outer-side via conductors 4a, 4b is realized.

By forming the outer-side via conductors 4a, 4b at the same time as firing the intermediate substrate 1, a positional relationship between, on one hand, the intermediate via conductor 6 and the conductor pattern of the internal conductor layer 5 in the intermediate substrate 1 and, on the other hand, the outer-side via conductors 4a, 4b can be made to not be affected by variation in dimensional shrinkage and deformation at the time of firing.

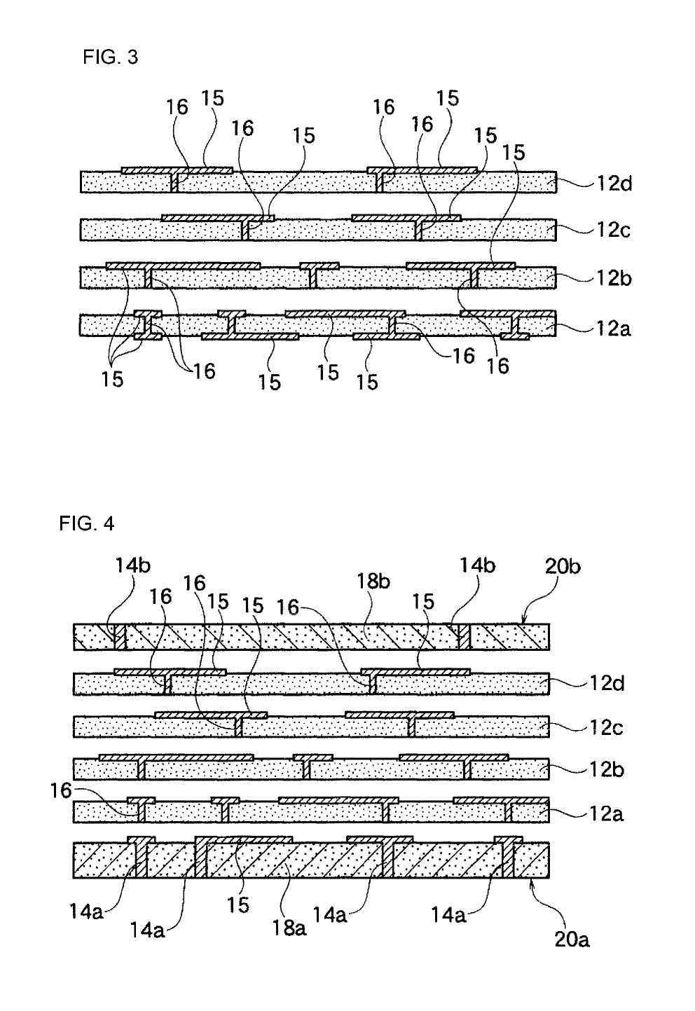

Specifically, first, as illustrated in FIG. 3, green sheets for a substrate 12a to 12d that come to configure the ceramic layers 2a to 2d of the intermediate substrate 1 consisting of the ceramic multilayer substrate are prepared. The green sheets for a substrate 12a to 12d are formed by creating a dielectric paste in a slurry form obtained by mixing a glass-ceramic powder and an organic vehicle and forming a film thereof by a doctor-blade method or the like on a support such as a polyethylene-terephthalate (PET) sheet. Any well-known ceramic powder and organic vehicle can be used.

In a situation of creating the glass-ceramic multilayer substrate that can be fired at the low temperature as the intermediate substrate 1, a ceramic powder and a glass powder are mixed in the dielectric paste to be used. At this time, it is favorable to select as appropriate this glass component and ceramic component based on a target relative dielectric constant and firing temperature.

As necessary, the green sheets for a substrate 12a to 12d are formed with a conductive paste for an inner layer 15 that comes to be the internal conductor layer 5 illustrated in FIG. 1A and are embedded with a conductive paste for an intermediate via 16 that comes to be the intermediate via conductor 6 illustrated in FIG. 1A. Moreover, while not illustrated, a conductor pattern for forming electronic elements such as an inductor, a capacitor, and a filter and another functional layer may be built in in the sheets 12a to 12d. The conductive paste for an intermediate via 16 is filled in a through hole formed in a predetermined position in the green sheets for a substrate 12a to 12d.

Furthermore, the internal conductor pattern 15 is formed by printing by screen printing or the like a metal conductive paste consisting or silver or the like in a predetermined shape on a surface of the green sheets for a substrate 12a to 12d or a face on an opposite side thereof.

The conductive paste is prepared by kneading a conductive material consisting of a conductive metal of various types such as Ag, Pd, Au, or Cu or an alloy thereof and an organic vehicle. The organic vehicle has a binder and a solvent as main components; while a mixing ratio with the conductive material and the like are arbitrary, the organic vehicle is normally compounded with the conductive material so the binder is 1 to 15% by mass and the solvent is 10 to 50% by mass. As necessary, an additive selected from various types of dispersants, plasticizers, and the like may be added to the conductive paste.

Meanwhile, as illustrated in FIG. 4, a component is prepared where a through hole is formed in green sheets for shrinkage suppression 18a, 18b having a shrinkage-suppression effect and conductive pastes for an outer-side via 14a, 14b are filled in this through hole. These green sheets for shrinkage suppression 18a, 18b are used for an object of suppressing shrinkage of the green sheets for a substrate 12a to 12d in an in-plane direction at the time of firing and forming the outer-side via conductors 4a, 4b consisting of the sintered metal conductor in the surface of the intermediate substrate 1.

In the present embodiment, the green sheets for shrinkage suppression 18a, 18b, unlike a general green sheet for shrinkage suppression, have the through hole formed as illustrated in FIG. 4 in a position corresponding to the through hole formed in the surface insulating layers 3a, 3b consisting of the organic material illustrated in FIG. 1A and have the conductive pastes for an outer-side via 14a, 14b filled therein. That is, the green sheets for shrinkage suppression 18a, 18b of the present embodiment have the conductive pastes 14a, 14b that come to be the outer-side via conductors 4a, 4b embedded in a predetermined pattern so as to penetrate a surface and a rear face.

The green sheets for shrinkage suppression 18a, 18b are green sheets configured by a ceramic material that does not shrink at a firing temperature; it adds an organic binder or the like to at least one type of ceramic powder selected from, for example, quartz, alumina, manganese oxide, zirconium oxide, calcium carbonate, mullite, fused quartz, cordierite, and the like and is made into a sheet shape by a doctor-blade method or the like.

The green sheets for shrinkage suppression 18a, 18b are obtained by mixing a composition including at least one type selected from among a quartz such as described above, cristobalite, and tridymite and a sintering aid—or a composition including tridymite, which is sintered by the firing to obtain the ceramic substrate, and an oxide that is not sintered by this firing—and an organic vehicle to create a paste in a slurry form and forming a film thereof in the sheet shape by the doctor-blade method or the like on a support such as a polyethylene-terephthalate (PET) sheet.

Next, the through hole, which is of a shape corresponding to the outer-side via conductors 4a, 4b, is provided in the green sheets for shrinkage suppression 18a, 18b. A machining method when providing the through hole is not particularly limited; for example, press or punching machining by a mold, laser machining, and the like can be mentioned. To form outer-side via conductors 4a, 4b with little tapering (no change in a diameter of the hole in a depth direction), punching or machining by a mold is desirable.

Next, the conductive pastes for an outer-side via 14a, 14b are filled in the through hole formed in the green sheets for shrinkage suppression 18a, 18b. A method of filling the conductive pastes is not particularly limited; for example, a printing method, such as screen printing, and the like can be mentioned. As the conductive pastes 14a, 14b, the same conductive paste used to form the internal conductor pattern of the ceramic substrate 1 can be used.

By filling the conductive pastes 14a, 14b in the through hole, sheets for forming an outer-side via conductor 20a, 20b, which consist of the green sheets for shrinkage suppression 18a, 18b, are obtained. In FIG. 4, the conductive paste for an inner layer 15 is printed as a conductive paste on a surface on one side (printing face) of the sheet for forming an outer-side via conductor 20a consisting of the green sheet for shrinkage suppression 18a. Note that the conductive paste for an inner layer 15 is not but may be printed on a surface on one side (printing face) of the sheet for forming an outer-side via conductor 20b consisting of the green sheet for shrinkage suppression 18b. The conductive paste for an inner layer 15 printed on the surface of the sheet for forming an outer-side via conductor 20a comes to be a conductor of an outermost face of the intermediate substrate 1 illustrated in FIG. 1A.

Next, the green sheet for shrinkage suppression 18a, the green sheets for a substrate 12a to 12d, and the green sheet for shrinkage suppression 18b are sequentially stacked on a flat base that is not illustrated to stack the sheets for forming a conductor and the green sheets for forming a substrate. At this time, the green sheets for a substrate 12a to 12d separated from the support and the green sheets for shrinkage suppression 18a, 18b may be stacked so each printing face faces downward and these may be pressurized upon being stacked.

Then, a stacked body of the green sheets for shrinkage suppression 18a, 18b and the green sheets for a substrate 12a to 12d is fired. As a firing atmosphere, for example, an oxidizing atmosphere, a reducing atmosphere, or the like can be used; specifically, it is favorable to use the atmosphere. As a result of shrinkage in the in-plane direction of the green sheets for a substrate 12a to 12d at the time of firing being suppressed by an action of green sheets for shrinkage suppression 13a, 13b configuring the sheets for forming an outer-side via conductor 20a, 20b and these shrinking only in the thickness direction, a shrinkage rate of, for example, ±1% or less is realized in the ceramic substrate 1 that comes to be obtained. A dimensional precision at this time is 0.1% or less and is extremely favorable. Moreover, by further optimizing the shrinkage rate, a more excellent dimensional precision of 0.05% or less can be ensured. Note that to increase a shrinkage-suppression effect, a normal green sheet for shrinkage suppression not formed with a through hole may be further stacked on outer sides of the sheets for forming an outer-side via conductor 20a, 20b.

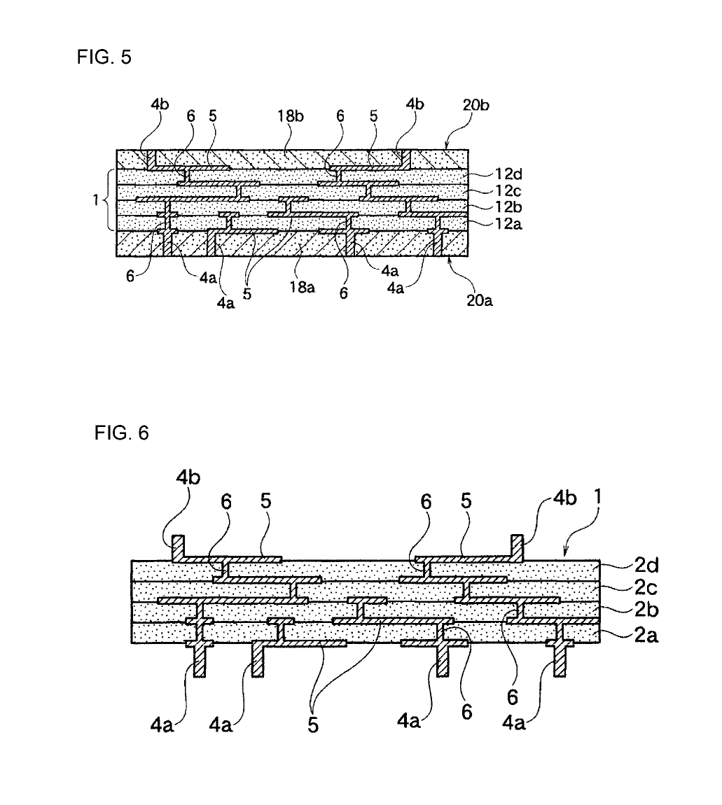

Furthermore, by performing firing, the conductive pastes for an outer-side via 14a, 14b held respectively in the green sheets for shrinkage suppression 18a, 18b configuring the sheets for forming an outer-side via conductor 20a, 20b and the conductive paste for an inner layer 15 adhere to the surface and a rear face of the fired intermediate substrate 1 illustrated in FIG. 5. Moreover, a sintering reaction of metals in the conductive pastes for an outer-side via 14a, 14b and the conductive paste for an inner layer 15 progresses. By this, the conductive pastes for an outer-side via 14a, 14b are sintered together with the conductive paste for an inner layer 15 or the conductive paste for an intermediate via 16 and, as illustrated in FIG. 5, outer-side via conductors 4a, 4b integrated with the intermediate via conductor 6 or the internal conductor layer 5 are obtained.

After firing, the green sheets for shrinkage suppression 18a, 18b configuring the sheets for forming a conductor 20a, 20b are in a state of being peeled readily due to not being sintered at the firing temperature of the green sheets for a substrate 12a to 12d. Because of this, after firing ends, these green sheets for shrinkage suppression 18a, 18b are removed, leaving the outer-side via conductors 4a, 4b.

As a method of removing only the green sheets 18a, 18b and leaving the outer-side via conductors 4a, 4b, for example, methods such as a sandblasting method, a wet-blasting method, and a treatment by a supersonic wave in water are conceivable. By this, as illustrated in FIG. 6, an intermediate substrate 1 can be obtained where the outer-side via conductors 4a, 4b integrated with the intermediate via conductor 6 or the internal conductor layer 5 protrude from the surface and the rear face of the intermediate substrate 1.

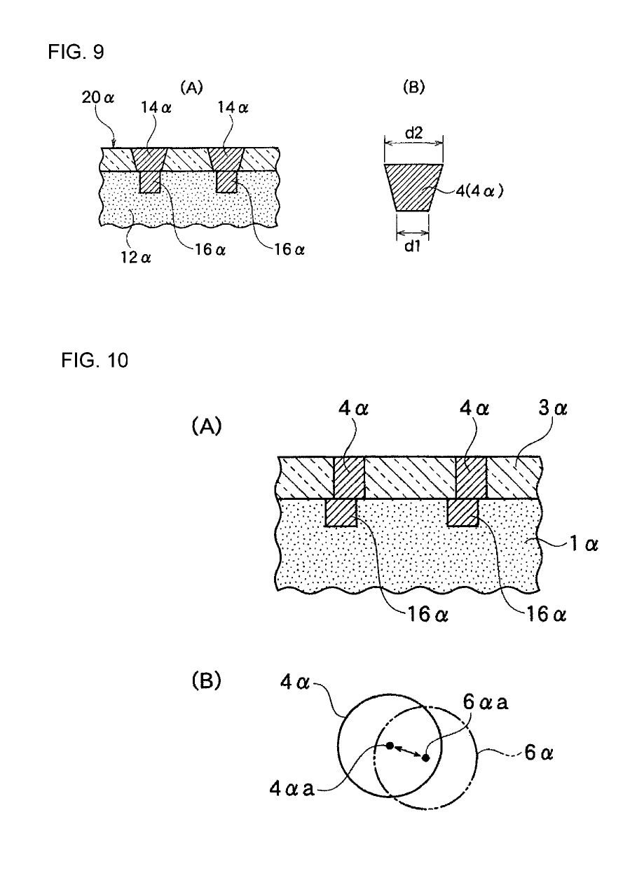

At this time, with a sintered metal conductor 4 (see (B) in FIG. 9) that comes to be the outer-side via conductors 4a, 4b, which have an electrical connection function, a difference between a dimension d1 of a narrowest portion of the via conductor and a dimension d2 of a broadest portion thereof is desirably 10% or less than the dimension d2 of the broadest portion. In a situation where this dimensional difference is large, electrical loss may increase in a high-frequency band such as a millimeter wave and a microwave. This is thought to be one cause of electrical loss due to local concentration in an electrical field becoming more likely to arise in a conductor through which an electrical signal passes in a situation where there is variation in a shape.

For example, the difference in dimension between the narrowest portion and the broadest portion of the sintered metal conductor 4 configuring the via conductors 4a, 4b referred to here can be represented as (d2−d1) in the situation of (B) in FIG. 9 where the dimension of the narrowest portion of the sintered metal conductor 4 is d1 and the dimension of the broadest portion thereof is d1. Note that (B) in FIG. 9 illustrates a cross section of a center portion of the sintered metal conductor 4 configuring the via conductors 4a, 4b.

At this time, it is understood that the sintered metal conductor 4 having an appropriate sinterability is desirable in obtaining a stable shape. Specifically, it is thought that a sintering density of the sintering metal being 80 to 95% is desirable. When the sintering density is low, a quality defect such as penetration of plating is more likely to arise, and in a situation where the sintering density is too high, controlling the shape is difficult. This is thought to be because sintering is performed in the sheets for shrinkage suppression 18a, 18b, where fundamentally no dimensional change arises; therefore, when a stress of shrinkage is too strong, a difference in shrinkage behavior with a peripheral portion becomes too great, causing a pre-sintering shape to be less likely to be maintained.

It is thought that by an appropriate sintering density, stress arising due to the difference in shrinkage behavior can be reduced, resulting in the shape becoming stable. These controls become more important in a situation of molding via conductors 4a, 4b of a large height.

Note that the sintering density is made to be an occupied area ratio of the metal in a cross section of the sintered metal.

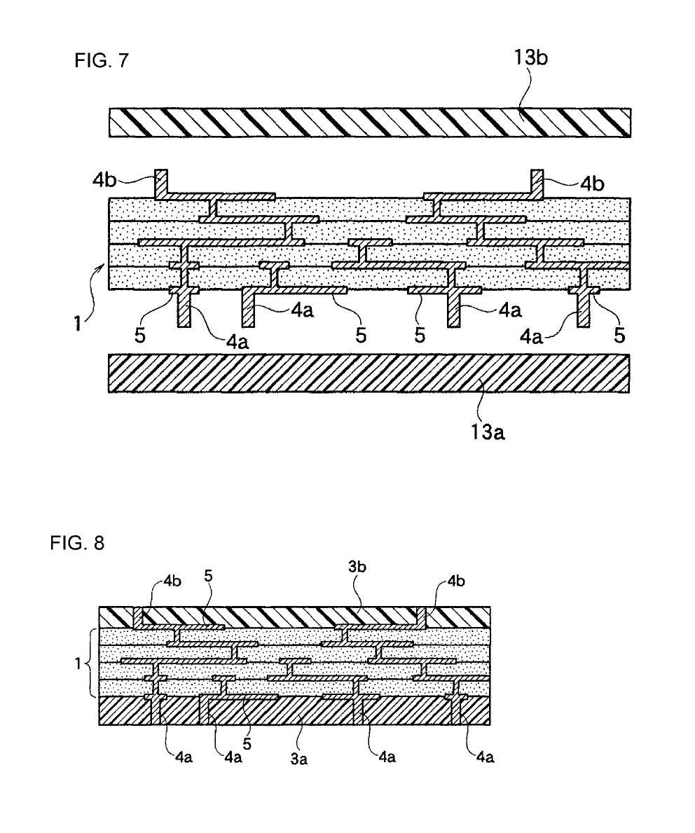

Next, as illustrated in FIG. 7 and FIG. 8, by forming the surface insulating layers 3a, 3b consisting of the organic material on the surface and the rear face of the intermediate substrate 1 illustrated in FIG. 6, the multilayer interconnection substrate for high frequency 10 illustrated in FIG. 1A is obtained. As a method of affixing the intermediate substrate 1 consisting of the ceramic multilayer substrate and the surface insulating layers 3a, 3b consisting of the organic material, general pressing and the like are also conceivable, but damage of the ceramic multilayer substrate readily becomes a problem. Therefore, to achieve suitable adhesion between the intermediate substrate 1 and the surface insulating layers 3a, 3b while preventing damage of the intermediate substrate 1, affixing using a press device operating on the principle of an isotropic press such as a vacuum lamination device such as below is preferable.

The resin sheets 13a, 13b used to form the surface insulating layers 3a, 3b illustrated in FIG. 8 are formed as below. That is, a resin paste in a slurry form obtained by mixing a resin powder and an organic vehicle is created and this is coated by the doctor-blade method or the like on a support and dried into a sheet shape. The resin material made into a film on the support is preferably placed in a state of having sufficient liquidity at a time of affixing and is placed, for example, in a semi-cured state (B-stage state).

In a situation of using a thermosetting resin as a resin material, this is placed in the semi-cured state by applying a heat treatment. By placing the resin material in the semi-cured state, adhesion to the surface of the intermediate substrate 1 when affixing the resin sheets 13a, 13b to the intermediate substrate 1 consisting of the ceramic multilayer substrate improves, fillability of unevenness due to the outer-side via conductors 4a, 4b consisting of the sintered metal conductor improves, and further improvement of surface smoothness in the multilayer interconnection substrate for high frequency 10 ultimately obtained is realized.

Incidentally, it is also possible to form the surface insulating layers 3a, 3b on the surface and the rear face of the intermediate substrate 1 formed with the outer-side via conductors 4a, 4b partially protruding even by affixing, while heating and melting, a film of a thermoplastic resin not having a semi-cured state (B-stage state).

It is favorable to set a film thickness of the resin material in the resin sheets 13a, 13b illustrated in FIG. 7 that come to be the surface insulating layers 3a, 3b illustrated in FIG. 8 as appropriate according to a thickness of the surface insulating layers 3a, 3b consisting of the organic material, a surface state of the intermediate substrate 1, and the like that are necessary; however, a thickness at least greater than or equal to a height of warping or unevenness of the surface of the intermediate substrate 1 is necessary, which is made to be, for example, 50 μm to 300 μm.

Furthermore, as described above, various types of thicknesses can be selected by design as appropriate for the surface insulating layers 3a, 3b consisting of the organic material at this time, but from a viewpoint of configuring the antenna as well, about 50 to 300 μm is desirable. In a situation of disposing the antenna, wiring is often formed similarly for connection, and in this situation, a characteristic impedance of this wiring needs to be a constant impedance of 50Ω or the like. In a situation where the thickness of the surface insulating layers 3a, 3b is thin, a width of the wiring needs to be narrowed, which is difficult in terms of manufacturing; conversely, in a situation where this is thick, the width of the wiring needs to be widened, which requires area and is undesirable from a viewpoint of size reduction.

As the support for forming the resin sheets 13a, 13b illustrated in FIG. 7, for example, a resin film such as polyethylene terephthalate or a metal foil such as copper foil can be used.

Note that a surface treatment may be performed on the intermediate substrate 1 consisting of the ceramic multilayer substrate in advance of the affixing process of the resin sheets 13a, 13b. For example, the surface of the intermediate substrate 1 may be treated by a silane coupling material before affixing the resin sheet to the surface of the intermediate substrate 1. By doing so, conformability in affixing the resin sheets 13a, 13b and the intermediate substrate 1 can be improved, improving adhesion therebetween.

After performing affixing, the resin material configuring the resin sheets 13a, 13b is cured. For example, in a situation where the resin sheets 13a, 13b are formed by the thermosetting resin, it is favorable to affix the resin sheets 13a, 13b by a vacuum laminator device and afterward perform heating and pressurizing in continuation therefrom in the same vacuum laminator device. By this, curing of the resin material can be performed and, as illustrated in FIG. 8, the surface insulating layers 3a, 3b consisting of the resin sheets 13a, 13b are formed on the surface of the intermediate substrate 1.

Curing conditions in a situation of using the vacuum laminator device need to be set as appropriate according to a type of the surface insulating layers 3a, 3b (the resin material of the resin sheets 13a, 13b); for example, a temperature is made to be 150° C. to 180° C. Moreover, it is favorable to make a pressure at a time of curing to be 1 MPa to 0.8 MPa. Time required for pressurization fluctuates according to the type of the surface insulating layers 3a, 3b but is about 1 hour to 10 hours.

By a manufacturing method such as above, the surface insulating layers 3a, 3b are respectively formed on the surface and the rear face of the intermediate substrate 1 consisting of the ceramic multilayer substrate and a multilayer interconnection substrate for high frequency such as illustrated in FIG. 1A is obtained.

Note that in a situation where, for example, after forming the surface insulating layers 3a, 3b consisting of the organic material, the outer-side via conductors 4a, 4b consisting of the sintered metal conductor do not penetrate the surface insulating layers 3a, 3b, a surface of the surface insulating layers 3a, 3b may be ground to expose a portion of the outer-side via conductors 4a, 4b to the surface of the surface insulating layers 3a, 3b.

Next, as illustrated in FIG. 1A, an outer-side conductor layer 7b that comes to be a pattern conductor for an antenna is formed on the surface of the surface insulating layers 3a, 3b consisting of the organic material and an outer-side conductor layer 7a that comes to be a terminal conductor pattern for mounting is formed on an opposite face thereof. A method of forming these conductor patterns is not particularly limited. For example, it is favorable to form a conductor film of Cu or the like on the surface insulating layers 3a, 3b by a sputter treatment, a plating treatment, or the like and afterward machine the conductor film into a predetermined pattern by photolithography technology and etching or the like. The outer-side via conductor 7a is formed on an outer surface of the surface insulating layer 3a and is electrically connected to the outer-side via conductor 4a. The outer-side conductive layer 7b is formed on an outer surface of the surface insulating layer 3b and is electrically connected to the outer-side via conductor 4b.

As above, in the present embodiment, after forming the outer-side via conductors 4a, 4b consisting of the sintered metal conductor protruding in, for example, the columnar shape on the surface of the intermediate substrate 1 consisting of the ceramic multilayer substrate, the surface insulating layers 3a, 3b are formed to be penetrated by the outer-side via conductors 4a, 4b consisting of the sintered metal conductor. By configuring in this manner, it becomes possible to form a multilayer interconnection substrate for high frequency with an antenna with precision and without impairing electrical characteristics.

Furthermore, in the present embodiment, it is possible to perform wiring by forming the surface insulating layers 3a, 3b consisting of the organic material with the low dielectric constant on the surface of the intermediate substrate 1 consisting of the glass-ceramic multilayer interconnection substrate with precision and without causing electrical loss.

Furthermore, in the present embodiment, the internal conductor layer 15 or intermediate via conductor 6 of the predetermined pattern in the intermediate substrate 1 consisting of the glass-ceramic multilayer substrate and the outer-side via conductors 4a, 4b penetrating the surface insulating layers 3a, 3b consisting of the organic material are configured by an integrally-sintered sintered metal, realizing an intermetallic bond therebetween. This enables electrical signal-loss suppression in a high-frequency band such as a millimeter wave and a microwave and is an element of suppressing characteristics reduction in the high-frequency band.

Furthermore, because intermetallic bonding takes place by the internal conductor layer 5 or the intermediate via electrode 6 and the outer-side via conductors 4a, 4b being configured by the integrally-sintered sintered metal, outer-side via conductors 4a, 4b with excellent positional precision and little tapering can be provided. Because of this, it becomes possible to maximize antenna characteristics and a multilayer circuit board for high frequency 10 with little quality variation and formed with an antenna with excellent characteristics can be provided.

Furthermore, because forming an antenna element on the surface insulating layers 3a, 3b that are low-dielectric-constant layers reduces a difference in dielectric constants with air, an electromagnetic wave is more readily propagated over the dielectric substrate surface and more readily radiated into a space in a direction perpendicular to an antenna face; as a result, gain improvement and radiation efficiency improvement of the antenna comes to be expected.

Furthermore, in the present embodiment, the inclination ratio between the narrowest portion and the broadest portion of the outer-side via conductors 4a, 4b is 10% or less. That is, with the sintered metal conductor 4 (see (B) in FIG. 9) that comes to be the outer-side via conductors 4a, 4b, the difference between the dimension d1 of the narrowest portion of the via conductor and the dimension d2 of the broadest portion thereof is 10% or less of the dimension d2 of the broadest portion.

Here, the inclination ratio above can be defined as below.

Inclination ratio (%)=[(longest distance between a center of gravity in a cross section of the via conductors 4a, 4b in a direction perpendicular to a direction in which an electrical signal is transmitted and an outer peripheral portion)−(shortest distance between the center of gravity in the cross section of the via conductors 4a, 4b in the direction perpendicular to the direction in which the electrical signal is transmitted and the outer peripheral portion)]/(longest distance between the center of gravity in the cross section of the via conductors 4a, 4b in the direction perpendicular to the direction in which the electrical signal is transmitted and the outer peripheral portion)

In this manner, by using a conductor with little change in a cross-sectional shape in the direction perpendicular to the direction in which the electrical signal is transmitted in the conductor using the sintered metal, compatibility is enabled with making the surface insulating layers 3a, 3b consisting of the organic material thick without impairing a quality of the via conductors 4a, 4b. This also enables forming via conductors 4a, 4b with little electrical loss without taking into consideration design factors such as the thickness of the surface insulating layers 3a, 3b consisting of the organic material.

Furthermore, in the present embodiment, a surface roughness Ra (μm) of the intermediate substrate 1 at an interface between the intermediate substrate 1 and the surface insulating layers 3a, 3b is in a range of 0.1≤Ra≤1.0.

By controlling the surface state of the intermediate substrate 1 consisting of the glass-ceramic material as above, high bonding and adhesion can be ensured and a module with no quality problems can be realized.

Generally, with an organic material and a glass-ceramic material, not only is there a difference in coefficients of linear expansion but also adhesion improvement by chemical bonding is difficult. Because of this, adhesion by a physical anchor by roughening a surface on a glass-ceramic side on which adhesion is to take place is desirable; however, if the roughness is too small, adhesion cannot be sufficiently ensured, which becomes a cause of peeling. Moreover, in a situation where this is too rough, when affixing the organic material, a void remains more readily at the interface, and reduction of reliability due to an influence of moisture or the like after productization becomes a concern. Therefore, it is thought that providing an appropriate surface roughness is a cause of high adhesion being able to be realized.

Furthermore, in the present embodiment, an average particle size D50 (μm) of the ceramic filler in an outermost layer of the intermediate substrate 1 at the interface between the intermediate substrate 1 and the surface insulating layers 3a, 3b is 0.2≤D50≤5.0. By configuring in this manner, more stable adhesion between the intermediate substrate 1 and the surface insulating layers 3a, 3b becomes possible.

The glass-ceramic material is configured by the glass and the ceramic filler; however, a surface state of the glass-ceramic at the time of firing is readily affected by a shape of the filler, and a form thereof depends on the filler.

With this, chemical etching or physical etching such as blasting can be used as a means of roughening; however, because a difference is seen in how the glass and the ceramic filler are etched, the filler shape is an important element in forming the surface state.

It is thought that by controlling the shape to be in a range such as above the surface of the intermediate substrate 1 enters a surface state where high adhesion can be expected. With this, it is thought that a microscopic roughness being formed due to the filler shape, thereby enabling a roughness suited to adhesion to be realized, is one cause. Moreover, as another element, this is thought to be because by the ceramic serving as this filler being present in a vicinity of the surface, it becomes possible to adhere the organic material to the ceramic, which is more chemically stable than glass, enabling more stable adhesion to be realized.

In the present embodiment, the relative dielectric constant of the surface insulating layers 3a, 3b is 2 or more and 4 or less. By making the dielectric constant small, a system including an antenna with more favorable performance can be realized. Generally, material loss of the organic material is greater than that of the ceramic, but by making the dielectric constant sufficiently small, a radiant efficiency of the antenna can be increased.

In the present embodiment, the intermediate substrate 1 is configured by the low-temperature-sintered glass-ceramic substrate. Providing a module integrally formed with an antenna on the surface insulating layers 3a, 3b of the low dielectric constant formed on the surface of this intermediate substrate 1 maximizes advantages of size reduction and cost reduction of the module by having the passive components such as the capacitor, the inductor, and the filter built in inside the substrate.

According to the method of manufacturing the multilayer interconnection substrate for high frequency 10 of the present embodiment, the multilayer interconnection substrate for high frequency 10 described above can be manufactured efficiently while suppressing warping of the intermediate substrate. That is, the multilayer interconnection substrate 10 can be formed by no-shrinkage firing.

By using no-shrinkage firing technology, the intermetallic bonding between the internal conductor layer 5 consisting of the wiring conductor in the intermediate substrate 1 consisting of the ceramic multilayer substrate or the intermediate via conductor 6 and the outer-side via conductors 4a, 4b can be realized with precision and more readily. With this, taking advantage of the via conductors 4a, 4b being able to be formed in the shrinkage-suppression sheets 18a, 18b that are not sintered at the time of firing used at the time of no-shrinkage firing is effective in facilitating formation of the via conductors 4a, 4b with the large height and little tapering.

### Second Embodiment

The multilayer interconnection substrate for high frequency is not limited to the embodiment described above, and those of various structures are illustrated. For example, it may be a multilayer interconnection substrate for high frequency 10a such as illustrated in FIG. 1B. This multilayer interconnection substrate for high frequency 10a is similar to the multilayer interconnection substrate for high frequency 10 illustrated in FIG. 1A other than as illustrated below, having similar actions and effects; description of common portions is omitted.

That is, in this multilayer interconnection substrate for high frequency 10a, a capacitor 7c1 or a terminal of an IC element 7c2 disposed on an outer side of the outer-side via conductor 4a formed in the surface insulating layer 3a is connected to the outer-side via conductor 4a. Moreover, an antenna element 7d disposed on an outer side of the outer-side via conductor 4b formed in the surface insulating layer 3b is connected to the outer-side via conductor 4b. Moreover, in this embodiment, a stacking count of intermediate insulating layers 2a to 2e configuring the intermediate substrate 1 and the shapes and dispositions of the internal conductor layer 5 and the intermediate via conductor 6 differ from the embodiment described above. Other configurations, actions, and effects are similar.

Note that the present invention is not limited to the embodiments described above and can be variously modified within the scope of the present invention.

For example, the outer-side via conductors 4a, 4b may be formed integrally sintered together with the internal conductor layer 5 or the intermediate conductor 6 without using the green sheets for shrinkage suppression 18a, 18b and using another sheet or another means.

### EXAMPLES

The present invention is described below based on more detailed examples, but the present invention is not limited to these examples.

### Creation of Green Sheet for Glass-Ceramic Multilayer Substrate

First, as the ceramic material for an intermediate substrate, an alumina-glass dielectric material is prepared. This is mixed with an organic binder and an organic solvent, and a green sheet for an intermediate substrate of a thickness of 40 μm is created by the doctor-blade method. At this time, as the glass, a glass powder that is mainly diopside crystals containing SiO₂, CaO, MgO, Al₂O₃, and SrO₂ is used. Moreover, as the alumina, an alumina powder whose average particle size D50=0.50 μm is used. Note that a composition is designed so a relative dielectric constant after firing is 7.5.

A via hole is provided in the green sheet for an intermediate substrate by the method described above, and the intermediate via conductor is formed by filling the conductive paste in this via hole. The internal conductor pattern is formed by printing the conductive paste in the predetermined shape on the green sheet for a substrate. With the conductive paste, Ag particles of an average particle size of 1.5 μm are used as the conductive material, the conductive paste being prepared by mixing the conductive material with an organic binder and an organic solvent.

### Creation of Green Sheet for Shrinkage Suppression

An alumina material whose average particle size D50=1.4 μm is prepared as the material for shrinkage suppression, and by mixing this with an organic binder and an organic solvent, the green sheet for shrinkage suppression (with no through hole) is created by the doctor-blade method. The thickness is determined as appropriate and as necessary.

### Creation of Sheet for Forming Conductor

An alumina powder whose average particle size D50=1.4 μm is prepared as the material for shrinkage suppression, and by mixing this with an organic binder and an organic solvent, a green sheet for shrinkage suppression of a thickness of 150 μm is created by the doctor-blade method. A through hole of a hole diameter of 100 μm is created at a predetermined pattern pitch by punching in this green sheet for shrinkage suppression. Next, the conductive paste an outer-side via is filled in this through hole by screen printing to obtain the sheet for forming the conductor. The conductive paste uses Ag particles of an average particle size of 1.5 μm as the conductive material and is prepared by mixing this conductive material with an organic binder and an organic solvent.

### Creation of Resin Sheet A

The resin sheet is created by coating a resin coating on a PET film by the doctor-blade method, drying this, and applying a heat treatment so the resin coating enters a semi-cured state (B-stage state). The resin coating is prepared by including an epoxy resin whose relative dielectric constant is 4 as the resin material and spherical silica as the filler at 10% by volume and dispersing and mixing these by a ball mill. The film thickness of the resin material on the PET film is controlled to be about 120 μm.

### Creation of Resin Sheet B

A resin sheet B is created by coating a resin coating on a PET film by the doctor-blade method, drying this, and applying a heat treatment so the resin coating enters a semi-cured state (B-stage state). The resin coating is prepared by including an epoxy resin whose relative dielectric constant is 2.4 as the resin material and spherical silica as the filler at 10% by volume and dispersing and mixing these by a ball mill. The film thickness of the resin material on the PET film is controlled to be about 120 μm.

### Creation of Resin Sheet C

A resin sheet C is created by coating a resin coating on a PET film by the doctor-blade method, drying this, and applying a heat treatment so the resin coating enters a semi-cured state (B-stage state). The resin coating is prepared by including an epoxy resin whose relative dielectric constant is 4 as the resin material and calcium titanate as the filler at 20% by volume and dispersing and mixing these by a ball mill. The film thickness of the resin material on the PET film is controlled to be about 120 μm.

### Example 1

A plurality of the green sheets for an intermediate substrate created as above is stacked, the sheet for forming a conductor is stacked on both faces of the stacked green sheets for a substrate, and stacking is further performed so a green sheet for shrinkage suppression of a thickness of 150 μm is stacked on both faces thereon. At this time, as illustrated in (A) in FIG. 9, a conductive paste for an intermediate via 16α in a green sheet for a glass-ceramic multilayer interconnection substrate 12α and a conductive paste for an outer-side via 14α formed in a sheet for forming a conductor 20α are stacked upon being positioned to match positions. Note that in the examples, description is omitted for components other than the conductive pastes for forming the via conductors.

Afterward, a stacked body obtained in this manner is placed in a normal mold where upper and lower punches are flat, pressurized for 7 minutes at 700 kg/cm², and afterward fired at 900° C. After firing, fired products of the sheet for forming a conductor and the green sheet for shrinkage suppression placed on both sides of the stacked green sheets for an intermediate substrate are removed by a sandblaster (product name: Pneuma-Blaster; made by Fuji Manufacturing Co. Ltd.). Sandblasting is performed using 1,000-mesh alumina at an air pressure of 0.17 MPa to 0.2 MPa.

By the above, a ceramic multilayer substrate provided with an outer-side via conductor consisting of a columnar sintered silver conductor of a height of around 140 μm on the surface of the intermediate substrate 1 consisting of the ceramic multilayer substrate is obtained. The fired ceramic substrate did not shrink in a planar direction overall but shrunk greatly only in a thickness direction. Dimensions of the ceramic substrate at this time were 150 mm×150 mm×0.5 mm.

Next, one resin sheet A of a thickness of 150 μm each is placed on both sides of the ceramic multilayer substrate formed with the sintered silver conductor on the surface, and these are affixed using a vacuum laminator device (model VAII-700, made by Meiki Co. Ltd.). For affixing conditions, a temperature is made to be 110° C. and a pressurizing time is made to be 60 seconds. A pressure at the time of affixing is made to be 0.5 MPa. In continuation therefrom, the resin material is cured in the vacuum laminator device. For curing conditions, a temperature is made to be 180° C. and a pressure is made to be 0.5 MPa. Curing took 4 hours.

A resin face of the cured substrate is ground using a grinder polishing machine (made by DISCO) to expose an upper face of the sintered silver conductor to a surface of the resin layer. Grinder polishing is performed under conditions of a polishing speed of 1 μm/sec., and a thickness of 20 μm of the resin layer is polished.

Next, with an aim of ensuring adhesion with the resin layer, an underlying electrode film is formed by Ti and Cu sputtering.

Afterward, a photosensitive film is affixed to the surface and the rear face and exposed and developed in the predetermined patterns to form the patterns by which the conductors of the surface and the rear face are to be formed; afterward, film formation is performed by copper plating on an opened portion of the photosensitive film.

Next, after peeling the photosensitive film, the Ti and Cu sputter films formed by sputtering and exposed to the surface are removed by etching.

Via the steps above, an organic-material layer is formed on the surface of the glass-ceramic multilayer interconnection substrate and a multilayer interconnection substrate formed with an antenna element on a surface thereof is created.

### Example 2

A multilayer interconnection substrate formed with an antenna element on a surface is created in a manner identical to example 1 other than the resin sheet formed on the surface and the rear face being the resin sheet B.

### Example 3

A multilayer interconnection substrate formed with an antenna element on a surface is created in a manner identical to example 1 other than the thickness of the green sheet for forming a conductor being 50 μm and the thickness of the resin sheet A formed on the surface and the rear face being 60 μm.

### Example 4

A multilayer interconnection substrate formed with an antenna element on a surface is created in a manner identical to example 1 other than the thickness of the green sheet for forming a conductor being 280 μm and the thickness of the resin sheet A formed on the surface and the rear face being 300 μm.

### Comparative Example 1

A plurality of the created green sheets for a glass-ceramic multilayer substrate is stacked, and stacking is performed so a green sheet for shrinkage suppression (with no through hole filled with the via-conductor paste) of a thickness of 75 μm is stacked on both faces of the stacked green sheets for a substrate. Note that a via-conductor paste disposed to match a position of the via conductor penetrating the organic-material layer molded at a subsequent step is disposed on an outermost layer of the stacked green sheets for a substrate so as to be exposed. A stacked body obtained in this manner is placed in a normal mold where upper and vertical punches are flat, pressurized for 7 minutes at 700 kg/cm², and afterward fired at 900° C. After firing, by removing the alumina particles in the green sheet for shrinkage suppression, a glass-ceramic multilayer interconnection substrate is created.

By the above, a ceramic multilayer substrate provided with a via conductor exposed to the surface of the ceramic multilayer substrate is obtained. The fired ceramic multilayer substrate did not shrink in a planar direction overall but shrunk greatly only in a thickness direction. Dimensions of the ceramic multilayer substrate at this time were 150 mm×150 mm×0.5 mm.

Next, one resin sheet A of the thickness of 150 μm each is placed on both sides of the ceramic multilayer substrate, and these are affixed using a vacuum laminator device (model VAII-700, made by Meiki Co. Ltd.). For affixing conditions, a temperature is made to be 110° C. and a pressurizing time is made to be 60 seconds. A pressure at the time of affixing is made to be 0.5 MPa. In continuation therefrom, the resin material is cured in the vacuum laminator device. For curing conditions, a temperature is made to be 180° C. and a pressure is made to be 0.5 MPa. Curing took 4 hours.

Next, a via hole of a diameter of 100 μm is formed in a predetermined position in the surface by a CO₂ laser. With positioning at this time, positioning of the via hole is performed using the alignment mark formed in advance on the glass-ceramic multilayer substrate.

Afterward, a via conductor by copper plating is molded by a process using plating. At this time, a copper-plating film is also formed simultaneously on the surface of the organic-material layer; moreover, after affixing a photosensitive film on the surface and the rear face and exposing and developing this in the predetermined patterns to form resist patterns by which the conductors of the surface and the rear face are to be formed, the copper-plating film of a resist opened portion is removed by etching, thereby creating a multilayer interconnection substrate formed with the predetermined pattern of the antenna or the like.

### Comparative Example 2

A multilayer interconnection substrate is created under conditions identical to comparative example 1 other than the thickness of the resin sheet A formed on both sides of the ceramic multilayer substrate being 60 μm.

### Comparative Example 3

A multilayer interconnection substrate is created under conditions identical to comparative example 1 other than the thickness of the resin sheet A formed on both sides of the ceramic multilayer substrate being 300 μm.

### Evaluation 1: Positional-Precision Evaluation of Via Conductor Penetrating Organic Material

A result of evaluating a positional precision of the via conductor penetrating the organic material for examples 1 to 4 and comparative examples 1 to 3 above is illustrated in table 1.

Note that as an evaluation method, as illustrated in (A) and (B) in FIG. 10, a positional shift amount between a via conductor 6α in an intermediate substrate 1α consisting of the sintered glass-ceramic multilayer substrate and a via conductor 4α penetrating a surface insulating layer 3α consisting of the organic material is evaluated.

Shift amounts of twenty-five predetermined locations common across all predetermined substrates among the substrates created as examples 1 to 4 and comparative examples 1 to 3 described above are measured, and an average value thereof is made to be the shift amount. That is, a center 6αa of the via conductor 6α in the intermediate substrate 1α and a center 4αa of the via conductor 4α penetrating the surface insulating layer 3α consisting of the organic material are sought by image processing, and an average value of these positional shift amounts is sought as the via-conductor shift amount illustrated in table 1.

TABLE 1

| | | | Difference in |
|---|---|---|---|
| | | | dimension between |
| | | | narrowest portion |
| | | Inclination | and broadest portion |
| | Via conductor shift | ratio of via | of via conductor |
| | amount (μm) | conductor (%) | (μm) |
| Comp. ex. 1 | 33.2 | 23.2% | 23.2 |
| Comp. ex. 2 | 31.3 | 15.1% | 15.1 |
| Comp. ex. 3 | 45.8 | 48.5% | 48.5 |
| Example 1 | 22.1 | 7.8% | 7.8 |
| Example 2 | 15.2 | 8.8% | 8.8 |
| Example 3 | 17.9 | 3.7% | 3.7 |
| Example 4 | 18.3 | 9.5% | 9.5 |

From the result described above, it is confirmed that by molding the via conductor penetrating the surface insulating layer consisting of the organic material at the same time as sintering the glass-ceramic multilayer substrate as in the examples enables the via conductor in the glass-ceramic multilayer substrate and the via conductor penetrating the organic material connecting the conductor pattern of the outermost face to be connected with more precision compared to a situation of molding the via conductor after molding the glass-ceramic multilayer substrate. The shift being small suggests that an increase in electrical loss of a connecting portion is less likely to arise, and it is thought that an excellent wiring substrate for high frequency is obtained.

With comparative examples 1 to 3, because the via conductor is formed by performing positioning with the substrate of a lower portion after molding the glass-ceramic multilayer substrate, there is a need to perform positioning using the alignment mark on the glass-ceramic multilayer substrate. Therefore, deformation of the substrate at the time of firing and recognition of the alignment mark being unfavorable on the glass-ceramic substrate are thought to be causes of positional precision being reduced in the situation of molding the via conductor after molding the glass-ceramic multilayer substrate.

Particularly, it is thought that in a situation where the organic-material layer is thick as in comparative example 3, recognition from above becomes even more difficult, thereby enlarging the shift.

### Evaluation 2: Shape Evaluation of Via Conductor Penetrating Organic Material

A shape of the via conductor penetrating the organic material is also evaluated for examples 1 to 4 and comparative examples 1 to 3 above, and a result thereof is illustrated in table 1.

Note that as an evaluation method, the difference between the narrowest portion and the broadest portion of the via conductor is evaluated in terms of the inclination ratio (%) described above. That is, the inclination ratio being small indicates a straight conductor with little thickness variation. For example, as illustrated in (B) in FIG. 9, it signifies a straight conductor where the difference in dimension (d2−d1) between the narrowest portion and the thicket portion in the via conductor 4α is small.

In the examples of the present invention, it is confirmed that with the via conductor 4α penetrating the surface insulating layer 3α consisting of the organic material, shape variation in a cross section in the direction perpendicular to the direction in which the electrical signal flows can be made small.

Shape variation becoming small provides excellence from viewpoints of both characteristics improvement and characteristics-variation suppression with regard to electrical characteristics as well.

### Examples 5 to 10

Examples are prepared where the particle size D50 (μm) of the alumina filer in the green sheet for a glass-ceramic multilayer interconnection substrate is respectively 0.5, 2, and 4.

After creating the green sheets for a glass-ceramic multilayer substrate using each alumina filler, ceramic substrates provided with a columnar sintered silver conductor of a height of about 140 μm on the surface of the substrate are created according to a procedure similar to example 1.

Next, before forming the surface insulating layer 3α consisting of the organic material, roughening of the surface of the intermediate substrate 1α is performed using an aqueous solution of hydrogen fluoride. At this time, by changing roughening conditions such as an amount of time, substrates with different surface roughnesses are created. An alumina-filler granularity (D50) in the created intermediate substrate 1α and the roughness of the surface (LTCC-portion surface roughness Ra (μm)) are illustrated in table 2.

Afterward, the surface insulating layer 3α consisting of the organic material is formed by the same method as example 1 and a multilayer interconnection substrate formed with an antenna element on the surface is created.

### Examples 11 to 13

Examples are prepared where the particle size D50 (μm) of the alumina filler in the green sheet for a glass-ceramic multilayer substrate is 0.1 and 0.8.

After creating the green sheets for a glass-ceramic multilayer substrate using each alumina filler, ceramic substrates provided with a columnar sintered silver conductor of a height of about 140 μm on the surface of the substrate are created according to a procedure similar to example 1.

Next, before forming the organic-material layer, roughening of the substrate surface is performed using an aqueous solution of hydrogen fluoride, similarly to examples 5 to 10. At this time, substrates with different surface roughnesses are created by changing roughening conditions such as an amount of time. An alumina-filler granularity in the created substrate and the roughness of the surface are illustrated in table 2.

Afterward, the organic-material layer is formed by the same method as example 1 and a multilayer interconnection substrate formed with an antenna element on the surface is created.

### Evaluation 3: Evaluation Relating to Adhesion Between Organic-Material Layer and Glass-Ceramic Multilayer Substrate

A result of evaluating adhesion between the surface insulating layer consisting of the organic material and the intermediate substrate consisting of the glass-ceramic multilayer substrate for examples 5 to 13 above is illustrated in table 2.

As an evaluation method, a peeling amount (μm) at an interface between the surface insulating layer 3α consisting of the organic material and the intermediate substrate 1α consisting of the glass-ceramic substrate at a time of dicing the glass-ceramic multilayer interconnection substrate using a blade is evaluated.

As dicing (cutting by a rotating blade) conditions, conditions such as below are used. Dicing is performed under conditions of a metal being used as a material of a dicing blade, a granularity of the mesh being made to be 800 μm, a blade whose blade width is 0.2 mm being used, a blade rotation speed being 30,000 rpm, and a cutting speed being 10 mm/sec.

TABLE 2

| | LTCC-portion | Filler | Via-conductor | Inclination | Peeling amount (μm) |
|---|---|---|---|---|---|
| | surface roughness | granularity | shift amount | ratio (%) of via | from cutting surface at |
| | Ra (μm) | D50 (μm) | (μm) | conductor | time of dicing |
| Ex. 5 | 0.3 | 0.5 | 22.5 | 5.5% | 5.2 |
| Ex. 6 | 0.3 | 4 | 19.2 | 8.4% | None |
| Ex. 7 | 0.5 | 2 | 22.9 | 8.2% | None |
| Ex. 8 | 0.9 | 2 | 20.4 | 7.9% | None |
| Ex. 9 | 0.5 | 0.5 | 17.9 | 9.2% | 3.8 |
| Ex. 10 | 0.9 | 4 | 18.3 | 8.4% | None |
| Ex. 11 | 0.08 | 0.1 | 19.9 | 7.6% | 12.3 |
| Ex. 12 | 0.08 | 0.8 | 19.8 | 6.8% | 8.7 |
| Ex. 13 | 0.3 | 0.1 | 21.5 | 8.2% | 10.5 |

It is confirmed that by making the roughness of the LTCC-substrate surface appropriate, a state where no peeling due to stress at the time of dicing occurs—that is, a state where adhesion is stronger—can be realized.

Furthermore, it is also confirmed concerning the particle size of the filler in the glass-ceramic that this being too small reduces adhesion and it is confirmed that an appropriate particle size enables higher adhesion to be realized.

In this manner, it is thought that by controlling the roughness of the LTCC-substrate surface and the shape of the filler in the glass-ceramic to further increase adhesion at the interface between the intermediate substrate 1α consisting of the LTCC substrate and the surface insulating layer consisting of the organic material causes high reliability to be realized.

### Comparative Example 4

A plurality of the created green sheets for an LTCC multilayer interconnection substrate is stacked, and stacking is performed so a green sheet for shrinkage suppression (with no through hole embedded with the conductive paste for a via) of a thickness of 75 μm is stacked on both faces of the stacked green sheets for a substrate. A stacked body obtained in this manner is placed in a normal mold where upper and lower punches are flat and pressurized for 7 minutes at 700 kg/cm² and afterward fired at 900° C.

Note that in the present structure, no sheet for forming a via conductor is used; pattern formation is performed in advance for an antenna element on the green sheet for an LTCC multilayer interconnection substrate disposed on the outermost layer, and by removing the alumina particles in the green sheet for shrinkage suppression after firing, a multilayer interconnection substrate formed with an antenna element on the surface is created. In comparative example 4, no surface insulating layer consisting of the organic material is formed on the surface of the substrate and the antenna element is formed directly on the surface of the LTCC substrate.

### Example 14

A multilayer interconnection substrate is created under the same conditions as example 1 other than the resin sheet B being formed on both sides of the ceramic multilayer substrate.

Dimensions of the ceramic multilayer substrate at this time were 150 mm×150 mm×0.75 mm.

### Example 15

A multilayer interconnection substrate is created under the same conditions as example 1 other than the resin sheet C being formed on both sides of the ceramic multilayer substrate.

Dimensions of the ceramic multilayer substrate at this time were 150 mm×150 mm×0.75 mm.

Evaluation 4: Evaluation Relating to Antenna Characteristics in Situation where Organic-Material Layer is Formed

Antenna characteristics are evaluated for examples 1, 14, and 15 and comparative example 4 above. A result thereof is illustrated in table 3. Note that with each, an antenna pattern designed so a center frequency of the antenna is 79 GHz is used. Relative dielectric constants in the table are relative dielectric constants measured by a blocking-cylindrical-waveguide method.

TABLE 3

| | | | | | | | Peeling |
|---|---|---|---|---|---|---|---|
| | | Organic- | | | | | amount |
| | LTCC- | material- | Antenna | Antenna | | | (μm) from |
| | portion | portion | bandwidth | radiant | Via | Inclination | cutting |
| | relative | relative | (MHz); | efficiency | conductor | ratio (%) of | surface at |
| | dielectric | dielectric | VSWR | (dB) at | shift amount | via | time of |
| | constant | constant | <2 MHz | 79 GHz | (μm) | conductor | dicing |
| Comp. Ex. 4 | 7.5 | None | 5400 | −0.31 | 18.8 | 8.1% | None |
| Ex. 1 | 7.5 | 4 | 6900 | −0.13 | 22.1 | 7.8% | None |
| Ex. 14 | 7.5 | 2.6 | 7500 | −0.11 | 21.5 | 6.9% | None |
| Ex. 15 | 7.5 | 6 | 6100 | −0.26 | 19.9 | 7.4% | None |

It is confirmed that by forming the organic material with the low dielectric constant into an antenna portion of a top layer as in the present examples, characteristics as the antenna improved. Moreover, it is also simultaneously confirmed that a lower dielectric constant is more favorable as a dielectric constant of the organic-material layer.

### INDUSTRIAL APPLICABILITY

By being able to realize little variation and high performance in a multilayer interconnection substrate formed with an antenna element on a surface, it becomes possible to provide a multilayer interconnection module substrate, for which development can be expected hereafter, that can contribute to size reduction and high functionalization in a system of high-speed data transmission, an in-vehicle radar, or the like used in a high-frequency band such as a microwave or a millimeter wave.

### REFERENCE SIGNS LIST

1 Intermediate substrate
2a to 2e Intermediate insulating layer
3a, 3b Surface insulating layer
4a, 4b Outer-side via conductor
5 Internal conductor layer
6 Intermediate via conductor
7a, 7b Outer-side conductor layer
7c1 Capacitor
7c2 IC element
7d Antenna element
10 Multilayer interconnection substrate for high frequency
12a to 12d Green sheet for a substrate
14a, 14b Conductive paste for an outer-side via
15 Internal conductor pattern
16 Conductive paste for an intermediate via
18a, 18b Green sheet for shrinkage suppression
20a, 20b Sheet for forming an outer-side via conductor

What is claimed is:

1. A multilayer interconnection substrate for high frequency, comprising:
an intermediate substrate where an internal conductor layer of a predetermined pattern is formed between intermediate insulating layers consisting of a glass-ceramic or on a surface of the intermediate insulating layer;
an intermediate via conductor that penetrates the intermediate insulting layer and connects the internal conductor layers present in different interlayer positions to each other;
a surface insulating layer consisting of an organic material integrally formed on at least one surface of the intermediate substrate; and
an outer-side via conductor that penetrates the surface insulating layer, wherein:
the outer-side via conductor is comprised of a sintered metal integrally sintered with the internal conductor layer or the intermediate via conductor; and
a relative dielectric constant of the surface insulating layer is lower than a relative dielectric constant of the intermediate insulating layer.

2. The multilayer interconnection substrate for high frequency as set forth in claim 1, wherein an inclination ratio between a narrowest portion and a broadest portion of the outer-side via conductor is 10% or less.

3. The multilayer interconnection substrate for high frequency as set forth in claim 1 or 2, wherein a surface roughness Ra (μm) of the intermediate substrate at an interface between the intermediate substrate and the surface insulating layer is in a range of 0.1≤Ra≤1.0.

4. The multilayer interconnection substrate for high frequency as set forth in claim 3, wherein an average particle size D50 (μm) of the ceramic filler in an outermost layer of the intermediate substrate at the interface between the intermediate substrate and the surface insulating layer is 0.2≤D50≤5.0.

5. The multilayer interconnection substrate for high frequency as set forth in any one of claims 1 to 4, wherein the relative dielectric constant of the surface insulating layer is 2 or more and 4 or less.

6. The multilayer interconnection substrate for high frequency as set forth in any one of claims 1 to 5, wherein the intermediate substrate is a low-temperature-sintered glass-ceramic substrate.

7. A method of manufacturing a multilayer interconnection substrate for high frequency as set forth in any one of claims 1 to 6, comprising:
preparing green sheets for shrinkage suppression where a conductive paste that comes to be the outer-side via conductor is embedded in a predetermined pattern so as to penetrate a surface and a rear face;
stacking the green sheets for shrinkage suppression respectively on both faces of a green-sheet stacked body that comes to be the intermediate substrate;
firing the green-sheet stacked body together with the green sheets for shrinkage suppression;
removing the fired green sheets for shrinkage suppression with leaving the outer-side via conductor consisting of the fired conductive past on the surface of the fired green-sheet stacked body to form an intermediate substrate with an outer-side via conductor; and
forming a surface insulting layer consisting of an organic material on a surface of the intermediate substrate with the outer-side via conductor.
